(19) United States
(12) Patent Application Publication
(10) Pub. No.: US 2025/0112099 A1
(43) Pub. Date: Apr. 3, 2025

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Ki Yeul YANG, Incheon (KR); Tai Hoon KIM, Seoul (KR); Sin Jae PARK, Incheon (KR); Jae Hun BAE, Seoul (KR)

(73) Assignee: Amkor Technology Singapore Holding Pte. Ltd., Valley Point #12-03 (SG)

(21) Appl. No.: 18/375,141

(22) Filed: Sep. 29, 2023

(51) Int. Cl. H01L 23/24; H01L 23/00; H01L 23/498; H01L 25/00; H01L 25/065

(52) U.S. Cl. CPC H01L 23/24; H01L 23/49811; H01L 23/49822; H01L 24/16; H01L 24/32; H01L 24/73; H01L 25/0655; H01L 25/50; H01L 2224/16227; H01L 2224/32225; H01L 2224/73204; H01L 2225/065; H01L 2924/3511

(57) ABSTRACT

In one example, an electronic device includes a substrate including a substrate inner side, a substrate outer side opposite to the substrate inner side, substrate lateral sides connecting the substrate inner side to the substrate outer side, a dielectric structure, a conductive structure, and a substrate internal stiffener at the substrate inner side. An electronic component is coupled to the conductive structure and includes a lower side proximate to the substrate inner side, an upper side opposite to the lower side, and a lateral side connecting the lower side to the upper side. An underfill is between the lower side of the electronic component and the substrate inner side and covering the substrate internal stiffener. An encapsulant covers a portion of the substrate inner side, a portion of the underfill; and a portion of the first electronic component. Other examples and related methods are also disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a cross-sectional view of an example electronic device.

FIG. 1B shows a top view of an example electronic device.

FIGS. 2A, 2B, 2C, 2D, 2E, 2F, and 2G show cross-sectional views of an example method for manufacturing an example electronic device.

FIGS. 3A, 3B, and 3C show cross-sectional views of an example method for manufacturing an example electronic device.

FIG. 4A shows a cross-sectional view of an example electronic device.

FIG. 4B shows a cross-sectional view of an example electronic device.

FIG. 4C shows a top view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

### DESCRIPTION

The present description includes, among other features, structures and associated methods that relate to electronic devices with 3D wafer level packaging. More particularly, structures and methods are described that improve the reliability of wafer level substrates, such as redistribution layer (RDL) substrates used, for example, in fine-pitch fan-out configurations. In some examples, one or more substrate stiffeners are used to reduce warpage, module bending, and stress-related defects, such as cracks. In some examples, a substrate external stiffener can provide a stopper function, which reduces unwanted bending when the electronic devices are attached to a next level of assembly. The structures and methods were found in practice to improve mechanical strength by 1.5 to 2 times compared to previous electronic devices.

In an example, an electronic device includes a substrate including a substrate inner side, a substrate outer side opposite to the substrate inner side, substrate lateral sides connecting the substrate inner side to the substrate outer side, a dielectric structure, a conductive structure including substrate inward terminals adjacent to the substrate inner side, and substrate outward terminals adjacent to the substrate outer side, and a substrate internal stiffener at the substrate inner side. A first electronic component is coupled to the substrate inward terminals and includes a first lower side proximate to the substrate inner side, a first upper side opposite to the first lower side, and a first lateral side connecting the first lower side to the first upper side. An underfill is between the first lower side of the first electronic component and the substrate inner side and covering the substrate internal stiffener. An encapsulant covers a portion of the substrate inner side, a portion of the underfill; and a portion of the first electronic component.

In an example, an electronic device includes a substrate including a substrate inner side, a substrate outer side opposite to the substrate inner side, substrate lateral sides connecting the substrate inner side to the substrate outer side, a dielectric structure, a conductive structure comprising substrate inward terminals adjacent to the substrate inner side and substrate outward terminals adjacent to the substrate outer side, and a substrate internal stiffener adjacent to the substrate inner side. A first electronic component is coupled to the substrate inward terminals and includes a first lower side proximate to the substrate inner side, a first upper side opposite to the first lower side, and a first lateral side connecting the first lower side to the first upper side. A second electronic component is coupled to the substrate inward terminals, laterally spaced apart from the first electronic component, and includes a second lower side, a second upper side opposite to the second lower side, and a second lateral side connecting the second lower side to the second upper side. An encapsulant covers a portion of the substrate inner side, a portion of the first electronic component, and a portion of the second electronic component.

In an example, a method of manufacturing an electronic device includes providing a substrate including a substrate inner side, a substrate outer side opposite to the substrate inner side, substrate lateral sides connecting the substrate inner side to the substrate outer side, a dielectric structure, a conductive structure including substrate inward terminals adjacent to the substrate inner side, and substrate outward terminals adjacent to the substrate outer side, and a substrate internal stiffener coupled to the substrate inner side. The method includes coupling a first electronic component to the substrate inward terminals, the first electronic component including a first lower side proximate to the substrate inner side, a first upper side opposite to the first lower side, and a first lateral side connecting the first lower side to the first upper side. The method includes providing a first underfill between the first lower side of the first electronic component and the substrate inner side and covering the substrate internal stiffener. The method includes providing an encapsulant covering at least a portion of the substrate inner side, at least portion of the first underfill; and at least a portion of the first electronic component. The method includes providing an external stiffener structure coupled to the substrate outer side. The method includes providing external interconnects coupled to the substrate outward terminals.

Other examples are included in the present disclosure. Such examples may be found in the figures, in the claims, or in the description of the present disclosure.

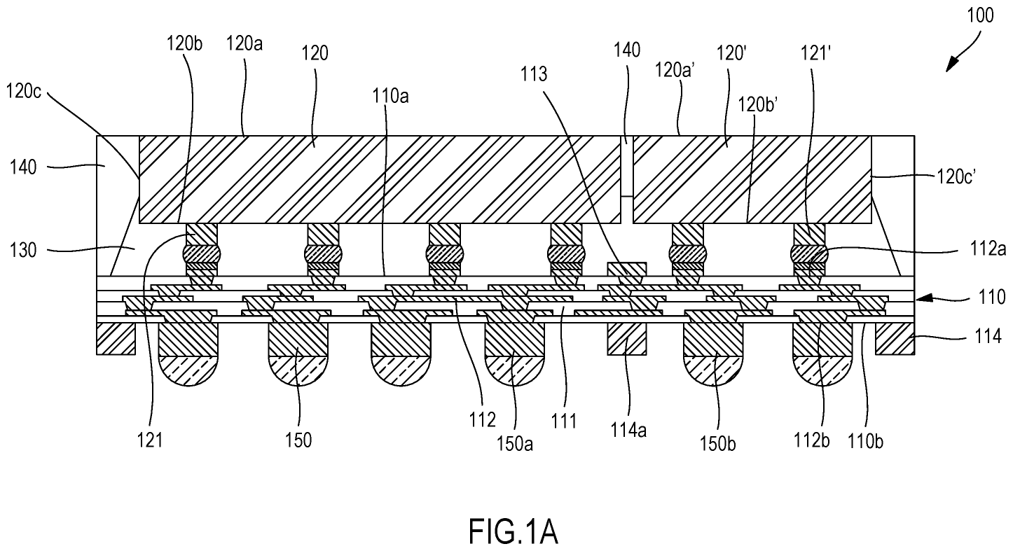

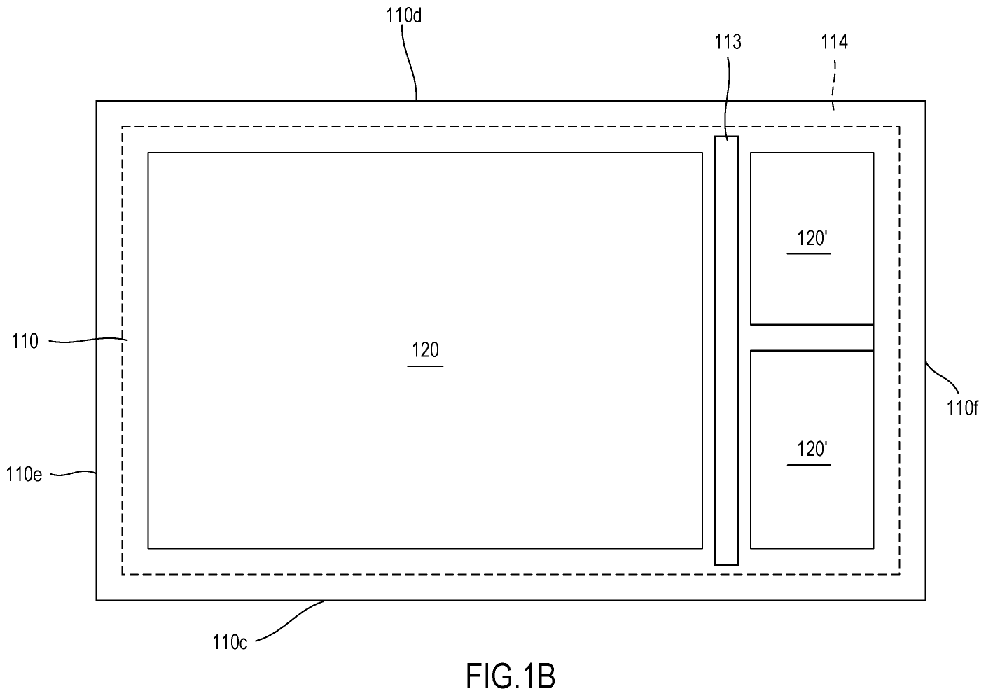

FIG. 1A shows a cross-sectional view of an example electronic device 100 and FIG. 1B shows a top view of an example electronic device 100. In the examples shown in FIGS. 1A and 1B, electronic device 100 can comprise a substrate 110, an electronic component 120, electronic component(s) 120′, underfill 130, encapsulant 140, and external interconnects 150.

In the present example, substrate 110 can comprise a substrate inner side 110a, a substrate outer side 110b opposite to substrate inner side 110a, a dielectric structure 111, a conductive structure 112, a substrate internal stiffener 113 adjacent to substrate inner side 110a, and external stiffener structure 114 adjacent to substrate outer side 110b.

In some examples, conductive structure 112 can comprise substrate inward terminals 112a proximate to substrate inner side 110a, and substrate outward terminals 112b proximate to substrate outer side 110b. Substrate inward terminals 112a can also be referred to as inner contact pads, and substrate outward terminals 112b can also be referred to outer contact pads.

In some examples, electronic component 120 comprises an upper side 120a, a lower side 120b opposite to upper side 120a, and a lateral sides 120c connecting upper side 120a and lower side 120b. In the present example, lower side 120b of electronic component 120 can be coupled to conductive structure 112 with component interconnects 121. In some examples, electronic component 120′ can be coupled to conductive structure 112 with component interconnects 121′. In some examples, underfill 130 can be interposed between lower side 120b of electronic component 120 and substrate 110, can surround component interconnects 121, can cover all or a portion of lateral sides 120c of electronic component 120, or can cover an exposed portion of substrate internal stiffener 113. In some examples, underfill 130 can be interposed between a lower side of electronic component 120 and substrate 110, can surround component interconnects 121′, and can cover all or a portion of a lateral sides of electronic component 120′. In some examples, encapsulant 140 is provided at a periphery or edge portion of substrate 110 to at least partially encapsulate or cover electronic component 120 and electronic component 120′. In some examples, portions of electronic component 120 (for example, upper side 120a) and electronic component 120′ are exposed from encapsulant 140 outside of electronic device 100. In other examples, encapsulant 140 can overlap and cover upper side 120a of electronic component 120 and the upper side of electronic component 120′. External interconnects 150 can be coupled to substrate outward terminals 112b.

Substrate 110, substrate internal stiffener 113, external stiffener structure 114, underfill 130, encapsulant 140, and external interconnects 150 can be referred to as an electronic package or package. The electronic package can protect electronic components 120 and 120′ from exposure to external elements and/or environments. The electronic package can also provide electrical coupling between electronic component 120 and electronic components 120′ and between electronic components 120 and 120′ and an external component or other electronic packages.

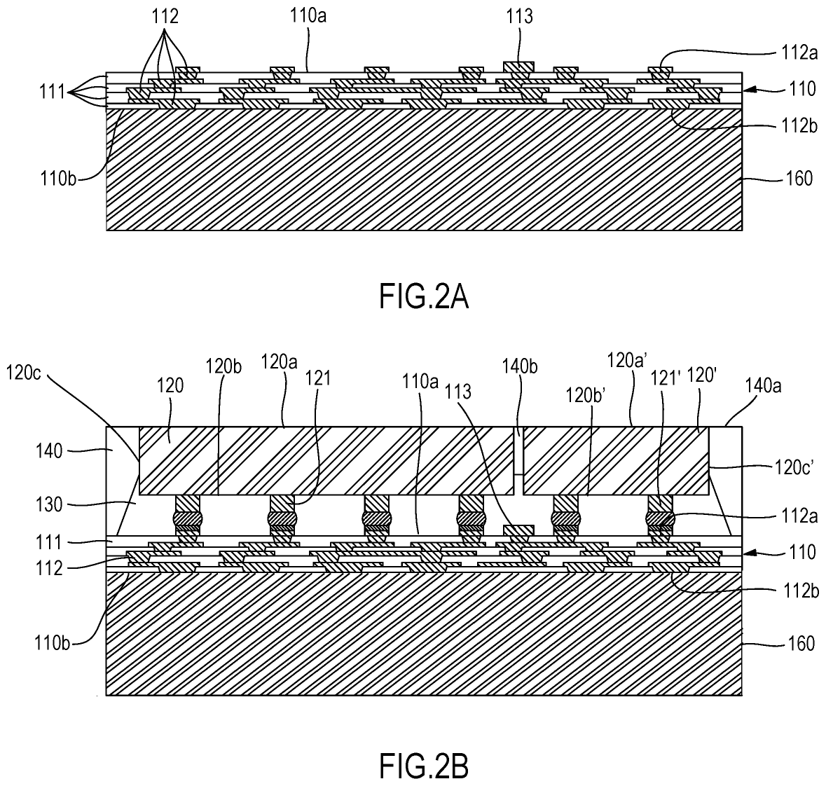

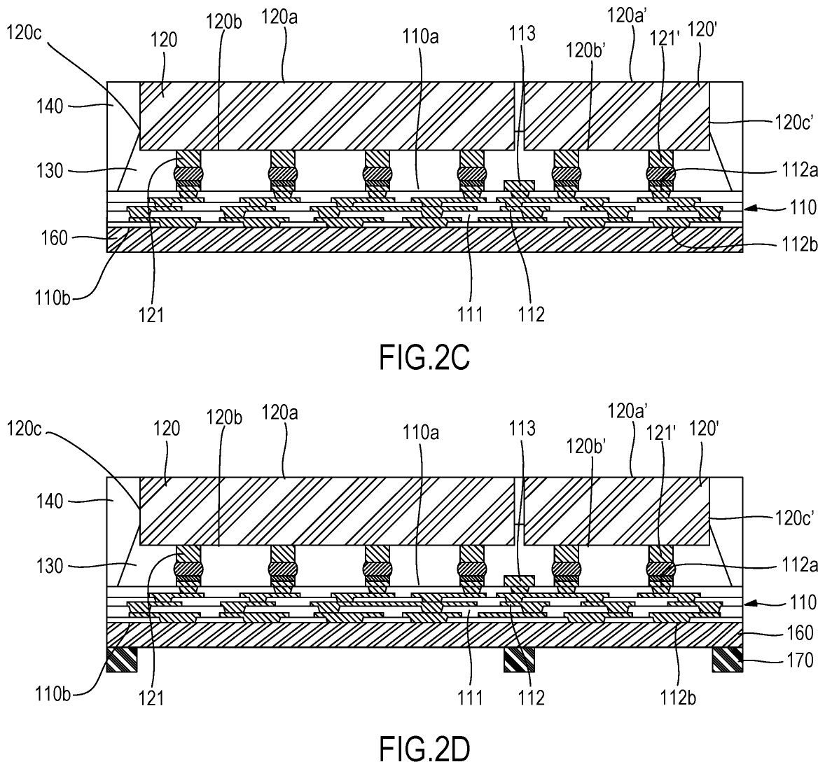

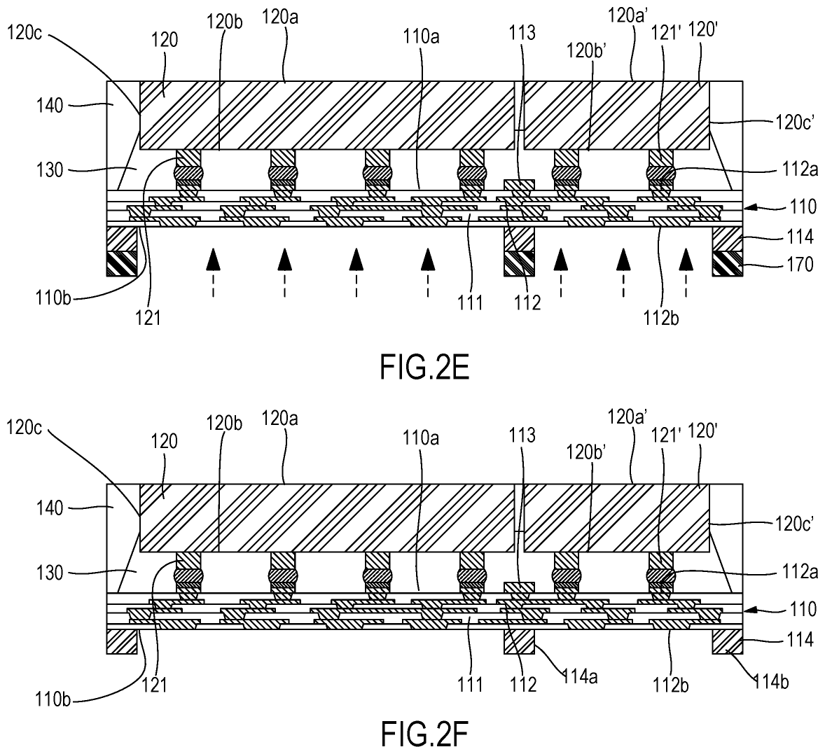

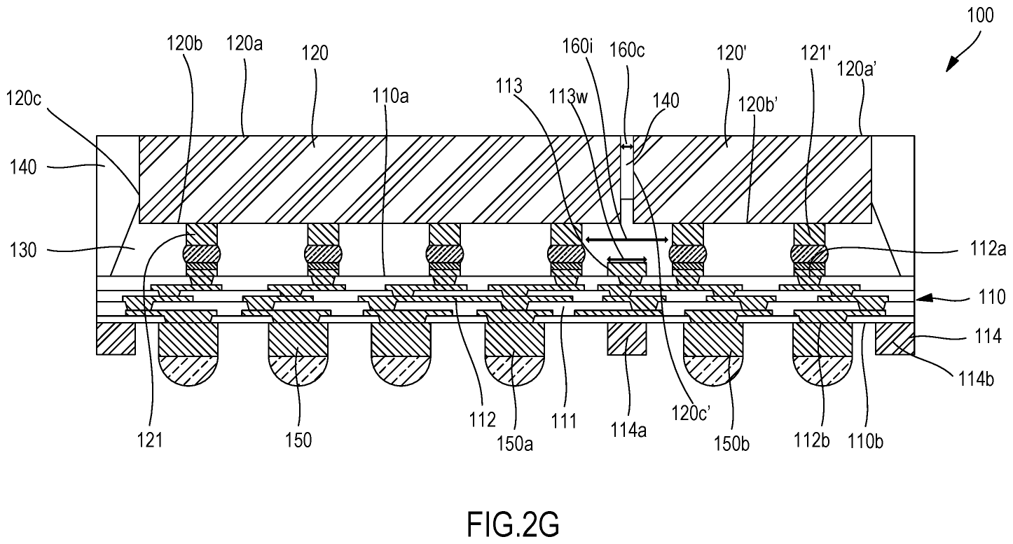

FIGS. 2A to 2G show cross-sectional views of an example method for manufacturing an example electronic device, such as electronic device 100 illustrated in FIGS. 1A and 1B.

FIG. 2A is a cross-sectional view of electronic device 100 at an early stage of manufacture. In the example shown in FIG. 2A, substrate 110 and substrate internal stiffener 113 can be provided on a carrier 160. In the present example, substrate 110 is shown as a redistribution layer (RDL) substrate.

RDL substrates can comprise one or more conductive redistribution layers (for example, conductive structure 112) and one or more dielectric layers (for example, dielectric structure 111) that (a) can be formed layer by layer over an electronic device to which the RDL substrate is to be electrically coupled, or (b) can be formed layer by layer over a carrier that can be entirely removed or at least partially removed after the electronic device and the RDL substrate are coupled together as in the present example. RDL substrates can be manufactured layer by layer as a wafer-level substrate on a round wafer in a wafer-level process, and/or as a panel-level substrate on a rectangular or square panel carrier in a panel-level process.

RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask.

The dielectric layers of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer.

Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Substrate 110 as disclosed herein, can comprise and be referred to as an RDL substrate.

In the example method of manufacture, carrier 160 can be provided. In some examples, carrier 160 can be provided as a round wafer in a wafer-level process, or as a panel-level substrate on a rectangular or square panel carrier in a panel-level process. In some examples, carrier 160 can comprise silicon, glass, ceramic, or other materials as known to one of ordinary skill in the art. In some examples, carrier 160 comprises one or more materials selected to provide external stiffener structure 114. Carrier 160 can also be referred to as a support carrier or support structure.

In the example method of manufacture, substrate 110 can be provided on carrier 160 in a buildup process (as described previously) to provide dielectric structure 111 and conductive structure 112 in an interleaved configuration. In some examples, substrate 110 can have an area of about 8 millimeters (mm)×8 mm to about 150 mm×150 mm. In some examples, substrate 110 can have a thickness about 10 μm to about 1000 μm.

In some examples, dielectric structure 111 can comprise or be referred to as one or more dielectrics, dielectric materials, dielectric layers, passivation layers, insulating layers, or protective layers. In some examples, dielectric structure 111 can have a structure where one or more dielectric layers are stacked. In some examples, dielectric structure 111 can comprise a polymer, polyimide (PI), benzocyclobutene (BCB), polybenzoxazole (PBO), bismaleimide triazine (BT), a molding material, phenolic resin, epoxy, silicone, or acrylate polymer. Dielectric structure 111 can be in contact with conductive structure 112. Dielectric structure 111 can expose portions of conductive structure 112. In some examples, dielectric structure 111 can maintain the external shape of substrate 110 and can structurally support conductive structure 112 and electronic components 120 and 120′.

In some examples, dielectric structure 111 can be provided by spin coating, spray coating, printing, oxidation, PVD, CVD, MOCVD, ALD, LPCVD, PECVD, or other processes as known to one of ordinary skill in the art. The upper and lower sides of dielectric structure 111 can be part of substrate inner side 110a and substrate outer side 110b of substrate 110 respectively. In some examples, the thicknesses of individual layers of dielectric structure 111 can range from about 1 μm to about 10 μm. The combined thickness of all layers of dielectric structure 111 can define the thickness of substrate 110. In some examples, the total thickness of dielectric structure 111 can range from about 10 μm to about 1000 μm.

In some examples, conductive structure 112 can comprise or be referred to as one or more conductors, conductive materials, conductive paths, conductive layers, redistribution layers (RDLs), wiring layers, traces, vias, lands, pads, or under bump metallization (UBM). In some examples, substrate inward terminals 112a can also be referred to as pads, lands, UBMs, or studs, and substrate outward terminals 112b can be referred to as two-step pads, pads, or lands.

In some examples, conductive structure 112 can comprise copper, aluminum, palladium, titanium, tungsten, titanium/tungsten, nickel, gold, silver, or tin/silver. Conductive structure 112 can be provided by sputtering, electroless plating, electrolytic plating, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or other processes as known to one of ordinary skill in the art. In some examples, a portion of conductive structure 112 can be exposed from substrate inner side 110a and from substrate outer side 110b of substrate 110. Substrate inner side 110a can also be referred to as substrate top side 110a, and substrate outer side 110b also can be referred to as substrate bottom side 110b. In some examples, the thickness of individual layers or portions of conductive structure 112 can range from 1 μm to about 10 μm.

In some examples, substrate inward terminals 112a are other than coplanar with substrate inner side 110a and instead, can protrude outward from dielectric structure 111 at substrate inner side 110a. In some examples, lateral sides or edges of substrate inward terminals 112a are devoid of dielectric material. In some examples, substrate inward terminals 112a can protrude outward and toward electronic component 120 or electronic component 120′. Substrate outward terminals 112b can be coupled to traces or vias that are internal to dielectric structure 111. In some examples, the traces or vias couple substrate outward terminals 112b to substrate inward terminals 112a. In some examples, substrate outward terminals 112b can be substantially coplanar with dielectric structure 111 at substrate outer side 110b. As described above, substrate 110 comprising dielectric structure 111 and conductive structure 112 can support electronic components 120 and 120′ and can couple (including electrical or mechanical coupling) electronic components 120 and 120′ and an external device to each other.

In other examples, substrate 110 can comprise a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. In further examples, substrate 110 can comprise a multi-layer substrate or a molded lead frame.

FIG. 2A shows substrate internal stiffener 113 provided on or adjacent to substrate inner side 110a of substrate 110. In some examples, substrate internal stiffener 113 can be provided coupled to dielectric structure 111 at substrate inner side 110a. In some examples, substrate internal stiffener 113 can be provided coupled to conductive structure 112 at substrate inner side 110a. In some examples and with reference to FIG. 1B, substrate internal stiffener 113 can be provided extending between a lateral sides 110c of substrate 110 towards a lateral sides 110d of substrate 110 opposite to lateral sides 110c. In this configuration, substrate internal stiffener 113 is generally perpendicular to lateral sides 110c and lateral sides 110d and generally parallel to opposing lateral sides 110e and 110f. In some examples, one or more of ends of substrate internal stiffener 113 are inset from lateral sides 110c and 110d so that substrate internal stiffener 113 does not extend all the way to lateral sides 110c or lateral sides 110d. In some examples, substrate internal stiffener 13 is offset from a center of substrate 110 towards lateral sides 110f. In some examples, lateral sides 110c and 110d or lateral sides 110e and 110f can be referred to as pairs of opposing lateral sides.

In some examples, substrate internal stiffener 113 can be provided substantially in a transverse form along the length direction and/or width direction of substrate 110. In some examples, substrate internal stiffener 113 can comprise a substantially straight shape where the sides and ends are generally linear and without undulations. In other examples, substrate internal stiffener 113 can comprise non-linear shapes including shapes pre-selected to reduce stress within electronic device 100. In some examples, substrate internal stiffener 113 can be provided on a portion of substrate 110 corresponding to a boundary region between electronic component 120 and electronic component 120′. In some examples, substrate internal stiffener 113 can be coupled including electrically coupled to conductive structure 112. In some examples, substrate internal stiffener 113 can be coupled to traces, vias, or substrate outward terminals 112b. In some examples, substrate internal stiffener 113 can be coupled including mechanically coupled to dielectric structure 111. In some examples, substrate internal stiffener 113 can comprise or be referred to as a stiffener, a first stiffener, a brace, a support, a reinforcement, a rib, or a protuberance. In some examples, substrate internal stiffener 113 can comprise a conductor. In other examples, substrate internal stiffener 113 can comprise a dielectric. In some examples, substrate internal stiffener 113 can be provided by plating or depositing copper, a copper alloy, aluminum, an aluminum alloy, gold, a gold alloy, silver, a silver alloy, nickel, a nickel alloy, palladium, a palladium alloy, tin silver, or another conductor on substrate 110. In some examples, substrate internal stiffener 113 can be provided by coating, depositing, or laminating a dielectric material or inorganic material, such as polyimide (PI), benzocyclobutene (BCB), or polybenzoxazole (PBO), resin, or Ajinomoto Buildup Film (ABF), on substrate 110.

In some examples, substrate inward terminals 112a and substrate internal stiffener 113 can be provided simultaneously using a bumping process. In some examples, when substrate inward terminals 112a are provided coupled to conductive structure 112, substrate internal stiffener 113 can also be provided. In some examples, similarly to substrate inward terminals 112a, substrate internal stiffener 113 can also be coupled to conductive structure 112.

In some examples, a different manufacturing process can be used to provide substrate internal stiffener 113 when substrate internal stiffener 113 comprises a different material than substrate inward terminals 112a. For example, a different material can be used to provide substrate internal stiffener 113 when substrate internal stiffener 113 comprises a dielectric material or an inorganic material.

Substrate internal stiffener 113 can provide increased structural integrity to suppress or reduce warpage or bending of substrate 110 or electronic device 100 due to, for example, a CTE difference. In some examples, substrate internal stiffener 113 can have a thickness (or height) of about 1 μm to about 100 μm. In some examples, substrate internal stiffener 113 can have a lateral width of about 300 μm to about 2500 μm. In some examples, the thickness of substrate internal stiffener 113 can be different than the thickness of substrate inward terminals 112a. For example, the thickness of substrate internal stiffener 113 can be greater or less than the thickness of substrate inward terminals 112a. In some examples, the thickness, width, and length of substrate internal stiffener 113 can be pre-selected in accordance with stress reduction requirements for electronic device 100.

In general, during high temperature processes, such as reflow processes, stress may be accumulated or concentrated in the boundary region (for example, accumulated in the underfill region) between electronic component 120 and electronic component 120′ due to a difference in coefficients of thermal expansion (CTE) of the between electronic component 120 and electronic component 120′ respectively as well as the CTEs of other components of electronic device 100. Substrate internal stiffener 113 can prevent or reduce the occurrence of, for example, cracking of underfill 130. Substrate internal stiffener 113 is configured to relax the stress at a stress accumulation point that can form between electronic component 120 and electronic component 120′. In addition, substrate internal stiffener 113 can provide increased structural integrity to suppress or reduce warpage or bending of substrate 110 or electronic device 100 due to a CTE difference.

FIG. 2B shows a cross-sectional view of electronic device 100 at a later stage of manufacture. In the example shown in FIG. 2B, electronic components 120 and 120′, underfill 130, and encapsulant 140 can be provided.

In an example method of manufacture, electronic components 120 and 120′ can be provided on substrate 110. In some examples, electronic component 120′ is laterally spaced apart from electronic component 120. Electronic component 120 can comprise upper side 120a, lower side 120b, and lateral sides 120c, and electronic component 120′ can comprise upper side 120a′, lower side 120b′, and lateral sides 120c′. In some examples, lower side 120b and lower side 120b′ comprise active surfaces of electronic components 120 and 120′ respectively and can face substrate 110. In some examples, upper side 120a and upper side 120a′ comprise inactive surfaces of electronic components 120 and 120′ respectively and can face away from substrate 110. Lower sides 120b and 120b′ are proximate to substrate inner side 110a and upper sides 120a and 120a′ are distal to substrate inner side 110a.

In some examples, electronic components 120 and 120′ can be coupled to conductive structure 112 of substrate 110. In some examples, electronic components 120 or 120′ can each comprise or be referred to as a semiconductor die, a semiconductor chip, or a semiconductor package. The die or chip can comprise an integrated circuit die separated from a semiconductor wafer. Electronic components 120 and 120′ can comprise digital signal processors (DSPs), network processors, power management units, audio processors, RF circuits, wireless baseband system on a chip (SoC) processors, sensors, memory, and application specific integrated circuits (ASIC). For instance, electronic component 120 can comprise a processor or ASIC, and electronic component 120′ can comprise a memory device, such as a package having stacked memory chips. In some examples, one or more of electronic components 120 or 120′ can be encapsulated semiconductor packages having an encapsulant that can be similar to encapsulant 140. Electronic components 120 or 120′ can comprise active or passive components. Electronic components 120 and 120′ can have a thickness of about 20 μm to about 1000 μm. Electronic components 120 and 120′ can perform calculation and control processing, store data, or remove noise from electrical signals.

In some examples, electronic components 120 and 120′ can comprise component terminals or bond pads adjacent to lower sides 120b and 120b′, and the component terminals can be electrically connected to substrate inward terminals 112a of substrate 110 through component interconnects 121 and 121′. Component interconnects 121 and 121′ can comprise or be referred to as bumps, pillars, pads, or solder balls. Component interconnects 121 and 121′ can be provided as electrical contacts between electronic components 120 and 120′ and substrate 110. Component interconnects 121 and 121′ can be coupled to conductive structure 112. For example, component interconnects 121 and 121′ can be coupled to inner contact pads 112a of conductive structure 112 by a mass reflow process, a thermal compression process, or a laser bonding process. In some examples, component interconnects 121 and 121′ can comprise copper (Cu), lead (Pb), tin (Sn), aluminum (Al), palladium (Pd), titanium (Ti), tungsten (W), titanium/tungsten (Ti/W), nickel (Ni), gold (Au), or silver (Ag). In other examples, component interconnects 121 and 121′ can be provided on lower side 120b of electronic component 120 or the lower side 120b′ of electronic component 120′ by electroplating, electroless plating, sputtering, PVD, CVD, MOCVD, ALD, LPCVD, or PECVD. For example, after providing a photoresist pattern for exposing the bond pads of electronic component 120 or electronic component 120′, component interconnects 121 and 121′ can be provided so as to contact exposed bond pads on lower side 120b of electronic component 120 or contact exposed bond pads on lower side 120b′ of electronic component 120′. Component interconnects 121 and 121′ can have a thickness and a diameter of about 1 μm to about 100 μm. Component interconnects 121 and 121′ can couple (including electrically or mechanically coupling) electronic components 120 and 120′ to substrate 110.

In the example method of manufacture, underfill 130 can be provided between substrate 110 and electronic components 120 and 120′. In some examples, underfill 130 can also be provided laterally between electronic component 120 and electronic component 120′. In some examples, underfill 130 can be in contact with or cover substrate 110 (for example, dielectric structure 111 or conductive structure 112), substrate inward terminals 112a, substrate internal stiffener 113, electronic components 120 and 120′, and/or component interconnects 121 and 121′.

In some examples, underfill 130 can be injected into a gap between electronic components 120 and 120′ and substrate 110 after electronic components 120 and 120′ are coupled to substrate 110. In other examples, underfill 130 can be pre-coated onto substrate 110 prior to electronic components 120 and 120′ being connected to substrate 110. Accordingly, electronic components 120 and 120′ can be pressed against underfill 130, and at the same time, component interconnects 121 and 121′ can penetrate underfill 130 to be electrically connected to substrate 110. In some examples, underfill 130 can be pre-coated on electronic components 120 and 120′ prior to electronic components 120 and 120′ being connected to substrate 110. Accordingly, electronic components 120 and 120′ can be pressed against underfill 130, and at the same time, component interconnects 121 and 121′ can be electrically connected to substrate 110. In some examples, a curing process (for example, a thermal curing process or a photocuring process) of underfill 130 can be performed.

In some examples, underfill 130 can comprise or be referred to as a capillary underfill (CUF), a molded underfill (MUF), a non-conductive paste (NCP), a non-conductive film (NCF), or an anisotropic conductive film (ACF). In some examples, underfill 130 can comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, or a fluxing underfill. In some examples, underfill 130 is interposed between lower side 120b of electronic component 120 and lower side 120b′ of electronic component 120′ and substrate inner side 110a. In some examples, underfill 130 can cover or surround component interconnects 121 and 121′. In some examples, underfill 130 contacts substrate inner side 110a of substrate 110 and lower sides 120b and 120b′ of electronic components 120 and 120′. In some examples, underfill 130 can cover, all or a portion of lateral sides 120c of electronic component 120 and lateral sides 120c′ of electronic component 120′ In some examples, underfill 130 can prevent or reduce occurrences of electronic components 120 and 120′ being separated from substrate 110. In some examples, the thickness of underfill 130 can range from about 80 μm to about 800 μm.

In the example method of manufacture, encapsulant 140 can be provided. In some examples, encapsulant 140 can cover substrate 110, electronic components 120 and 120′, and underfill 130. In some examples, encapsulant 140 can be in contact with substrate 110, underfill 130, and electronic components 120 and 120′. In some examples, encapsulant 140 can comprise epoxy resin or phenolic resin, carbon black, silica filler, or other materials as known to one of ordinary skill in the art. In some examples, encapsulant 140 can comprise or be referred to as a body, a molding, a mold compound, a resin, a sealant, a filler-reinforced polymer, or an organic body.

In some examples, encapsulant 140 can be on lateral sides 120c and 120c′ and upper sides 120a and 120a′ of electronic components 120 and 120′ respectively. In some examples, upper sides 120a and 120a′ of electronic components 120 and 120′ and a top side 140a of encapsulant 140 can be coplanar. In some examples, upper sides 120a and 120a′ of electronic components 120 and 120′ can be exposed from top side 140a of encapsulant 140 to the outside of electronic device 100. In some examples, a portion 140b of encapsulant is between lateral sides 120c of electronic component 120 and lateral sides 120c′ of electronic component 120′. Portion 140b is interposed between the lateral sides of electronic components 120 and 120′ that laterally face each other. In some examples, portion 140b overlies substrate internal stiffener 113. In some examples, a thermally conductive lid, a heat spreader, or a heat sink can be attached to exposed electronic components 120 and 120′. In some examples, a thermal interface material (TIM) and/or a back-side metallization (BSM) can be interposed between electronic components 120 and 120′ and the lid.

In some examples, encapsulant 140 can be provided by compression molding, transfer molding, liquid phase molding, vacuum lamination, paste printing, or film assist molding. Compression molding can be a process where a flowable resin is supplied into a mold in advance, and an electronic component is then put into the mold to cure the flowable resin, and transfer molding can be a process where a flowable resin is supplied from a gate (supply port) of a mold to the periphery of an electronic component and then cured. Encapsulant 140 can have a thickness of about 100 μm to about 1000 μm. Encapsulant 140 can protect electronic components 120 and 120′ from external elements or environmental exposure and can rapidly dissipate heat from electronic components 120 and 120′. In some examples, underfill 130 can be omitted, and encapsulant 140 can be filled between electronic components 120 and 120′ and substrate 110. In some examples, when the silica filler has a smaller size than the gap between electronic components 120 and 120′ and substrate 110, encapsulant 140 can replace the function of underfill 130.

FIG. 2C shows a cross-sectional view of electronic device 100 at a later stage of manufacture. In the example shown in FIG. 2C, a partial region or portion of carrier 160 can be removed to reduce the thickness of carrier 160. That is, an initial or first carrier thickness can be reduced to a second carrier thickness less than the first carrier thickness using a removal process. In some examples, a wafer support system can be attached to encapsulant 140 or electronic components 120 and 120′, and the partial region of carrier 160 can be removed. In some examples, the partial region of carrier 160 can be removed by mechanical grinding or chemical etching. In some examples, the wafer support system can be fixed, and a grinder rotates, thereby removing the partial region of carrier 160. In some examples, the removal process can be performed until the residual or remaining thickness of carrier 160 reaches about 1 μm to about 200 μm. In some examples, the remaining region or portion of carrier 160 can be used to provide external stiffener structure 114.

FIG. 2D shows a cross-sectional view of electronic device 100 at a later stage of manufacture. In the example shown in FIG. 2D, a selective removal process can be used to remove portions of carrier 160. In some examples, a mask 170, such as a patterned photoresist mask 170 or a photoresist pattern 170 can be provided adjacent to a lower side of carrier 160. In some examples, photoresist can be applied to the lower surface of carrier 160 and a photomasking exposure process and a photoresist developing process can be used to provide photoresist pattern 170 on carrier 160. The width of photoresist pattern 170 can be preselected in accordance with the desired dimensions of external stiffener structure 114.

FIG. 2E shows a cross-sectional view of electronic device 100 at a later stage of manufacture. In the example shown in FIG. 2E, a removal process, such as an etching process can be performed to remove unmasked portions or exposed portions of carrier 160.

In some examples, the unmasked portions of carrier 160 can be etched and removed by using photoresist pattern 170 as a mask. In some examples, a first portion or portions of carrier 160 can be removed by dry etching or wet etching. In some examples, in the case of dry etching, the partial region or the first portion of carrier 160 can be removed by providing an etching gas (e.g., Cl₂, HCl, HF, HBr, SF, etc.) in a plasma state to the partial region of carrier 160 while leaving a second portion of carrier 160 coupled to substrate outer side 110b. In some examples, after the dry etching, dielectric structure 111 and conductive structure 112 of substrate 110 can be exposed. In some examples, substrate outward terminals 112b of substrate 110 can be exposed.

FIG. 2F shows a cross-sectional view of electronic device 100 at a later stage of manufacture. In the example shown in FIG. 2F, mask 170 can be removed using, for example, a photoresist stripping process.

In some examples, photoresist pattern 170 can be removed with a liquid resist stripper. In some examples, the liquid resist stripper can comprise monoethanolamine, or 2-butoxy ethanol. In some examples, photoresist pattern 170 can be removed by oxygen-containing plasma. In some examples, photoresist pattern 170 can also be removed by 1-methyl-2-pyrrolidone (NMP) solvent. In some examples, once photoresist pattern 170 is dissolved, the solvent can be heated to about 80 degrees Celsius to reduce the presence of any residue on the remaining portions of carrier 160 used to provide external stiffener structure 114.

In this way, external stiffener structure 114 is provided attached to substrate outer side 110b of substrate 110. In some examples and with reference to FIG. 1B, external stiffener structure 114 can be provided in a substantially rectangular line shape along lateral sides 110c, 110d, 110e, and 110f of substrate 110. In some examples, external stiffener structure 114 can be provided as a series of straight lines or linear shapes that traverse along the length direction or width direction of substrate 110, without necessarily intersecting each other. In other examples, external stiffener structure 114 can comprise other shapes including non-linear shapes or shapes preselected to reduce stresses within electronic device 100 and to provide other features including a stopper feature.

External stiffener structure 114 can comprise substrate external stiffener 114a or substrate periphery stiffener 114b. In some examples, substrate internal stiffener 113 and substrate external stiffener 114a do not overlap each other on substrate 110. In other examples, substrate external stiffener 114a and substrate internal stiffener 113 can overlap or can be substantially collinear with each other. In some examples, substrate outer side 110b comprises a peripheral region and substrate periphery stiffener 114b extends around the peripheral region as illustrated, for example, in FIG. 1B.

In the present example, external stiffener structure 114 comprises the same material as carrier 160. For example, when carrier 160 comprises silicon, glass, or ceramic, external stiffener structure 114 also comprises silicon, glass, or ceramic. In some examples, external stiffener structure 114 can have a thickness of about 1 μm to about 200 μm. In some examples, external stiffener structure 114 can have a width of about 50 μm to about 600 μm. External stiffener structure 114 can suppress or reduce bending and warpage of electronic device 100. In some examples, external stiffener structure 114 can also function as a stopper. For example, when electronic device 100 is attached to a pick-and-place tool and then pressed by an external device, external interconnects 150 or substrate outward terminals 112b can be damaged as the outer periphery of substrate 110 first comes into contact with the external device. However, when external stiffener structure 114 is provided around the periphery region of substrate outer side 110b of substrate 110, external stiffener structure 114 (for example, substrate periphery stiffener 114b) first comes into contact with the external device, and thus the outer periphery of substrate 110 does not first come into contact with the external device, thereby suppressing damage to external interconnects 150 or substrate outward terminals 112b.

FIG. 2G shows a cross-sectional view of electronic device 100 at a later stage of manufacture. In the example shown in FIG. 2G, external interconnects 150 can be provided coupled to substrate outward terminals 112b. In some examples, a plating process or deposition process can be used to provide external interconnects 150 on substrate outward terminals 112b. External interconnects 150 can comprise or be referred to as conductive pillars, conductive balls, conductive bumps, or solder balls. In some examples, a plating or deposition process using copper, a copper alloy, aluminum, an aluminum alloy, gold, a gold alloy, silver, a silver alloy, nickel, a nickel alloy, palladium, a palladium alloy, or tin silver can be used to provide external interconnects 150 as conductive pillars on substrate outward terminals 112b. In some examples, flux can be provided on substrate outward terminals 112b, conductive balls can be dropped on the flux, and conductive balls can then be provided on substrate outward terminals 112b through a reflow process or a laser assisted bonding process to provide external interconnects 150. In some examples, external interconnects 150 can comprise tin, silver, lead, copper, Sn—Pb, Sn₃₇—Pb, Sn₉₅—Pb, Sn—Pb—Ag, Sn—Cu, Sn—Ag, Sn—Au, Sn—Bi, or Sn—Ag—Cu. In the present example, the thickness of external interconnects 150 is greater than the thickness of external stiffener structure 114 so that external interconnects 150 can attach to a next level of assembly. In some examples, the width of external interconnects 150 can greater than the width of external stiffener structure 114. In some examples, external interconnects 150 can have thicknesses or widths of about 0.01 mm to about 10 mm. External interconnects 150 can serve to couple including mechanically and electrically coupling electronic device 100 to an external device. In some examples, a substrate external stiffener 114a of external stiffener structure 114 can be provided between a first row or first column of external interconnects and a second row or second column of external interconnects. In some examples, substrate external stiffener 114a can be interposed between a first external interconnect 150a and a second external interconnect 150b in a cross-sectional view and at a location where substrate external stiffener 114a overlaps with substrate internal stiffener 113. In some examples, external stiffener structure 114 only has substrate external stiffener 114a under substrate internal stiffener 113. In some examples, substrate external stiffener 114a of external stiffener structure 114 and substrate internal stiffener 113 are in superimposition or collinear with respect to each other.

In some examples, an optional singulation process can be used in the example method of manufacture. In some examples, the singulation process can be performed using a cutting wheel, a laser beam, or a plasma singulation. In some examples, when multiple electronic devices 100 are manufactured in a form having rows or columns, electronic devices 100 can be separated into individual electronic devices 100 by the singulation process. In some examples, by singulating encapsulant 140, substrate 110, and external stiffener structure 114, individual electronic devices 100 can be provided. Accordingly, lateral sides of encapsulant 140, substrate 110, or external stiffener structure 114 can be coplanar. In some examples, the lateral sides of encapsulant 140, the lateral sides 110c, 110d, 110e, and 110f substrate 110, and the outer facing sides of external stiffener structure 114 can be referred to as singulated surfaces or sides.

Electronic device 100 can comprise component gap 160c between respective electronic components 120 and 120′, interconnect gap 160i between adjacent respective component interconnects 121 and 121′, and internal stiffener width 113w of substrate internal stiffener 113.

In electronic device 100, the relationship of internal stiffener width 113w with component gap 160c or interconnect gap 160i be configured to enable substrate internal stiffener 113 to provide increased structural integrity to electronic device 100 or substrate 110. Through research and experimentation, applicant has found a tendency for stress concentration in component gap 160c, such as along the interface of lateral side 120c′ of component 120′ with encapsulant 140 and underfill 130, extending to damage substrate 110 about such stress concentration line. As applicants found, such stress concentration can be more pronounced where the sidewall of component 120′ itself comprises an encapsulant interfacing with encapsulant 140 or underfill 130.

To address such stress concerns applicant has included substrate internal stiffener 113 along such stress concentration, designing the dimensions between the different elements to minimize the distance between electronic components 120 and 120′, while permitting sufficient separation and avoid shorts during processing between substrate inward terminals 112a and substrate internal stiffener 113, and between component interconnects 121,121′ and substrate internal stiffener 113.

In some examples, such as when considering the above, component gap 160c can be about 50 μm to about 100 μm, or about 70 μm, interconnect gap 160i can be about 500 μm to about 3000 μm, and internal stiffener width 113w of substrate internal stiffener 113 can be about 300 μm to about 2500 μm. In some examples, the ratio between and internal stiffener width 113w and interconnect gap 160i can be about 3/5 to about 5/6. In some examples, substrate internal stiffener 113 can overlap with lateral side 120c or 120c′ of electronic component 120 or 120′ by about 50 μm to about 200 μm (i.e., the length of the overlapping portion can be about 50 μm to about 200 μm). In some examples, such overlap can extend under electronic component 120′ but need not extend under electronic component 120. In some examples, the length of the overlap can be about 100 μm. In some examples, the center of internal stiffener width 113w can be offset from the center of component gap 160c.

In some examples, substrate external stiffener 114a can overlap or can be substantially collinear across substrate 110 with substrate internal stiffener 113. In some examples, substrate external stiffener 114a can be configured or positioned similar to substrate internal stiffener 113 to address similar stress considerations described above. For example, substrate external stiffener 114a can overlap with lateral side 120c or 120c′ of electronic component 120 or 120′, such as by about 100 μm to about 200 μm. In some examples, such overlap can extend under electronic component 120′ but need not extend under electronic component 120. There can be implementations where the center of the width of substrate external stiffener 114a can be offset from the center of component gap 160c.

Dimensions of external stiffener structure 114 can be configured to provide structural integrity to address, for example, warpage of substrate 110, or the stress conditions described above around component gap 160c. For example, the width of substrate external stiffener 114a can be about 300 μm to about 2500 μm, or can correspond with internal stiffener width 113w, to address stress concentration. As another example, the width of substrate periphery stiffener 114b can be about 50 μm to about 600 μm to address warpage of substrate 110.

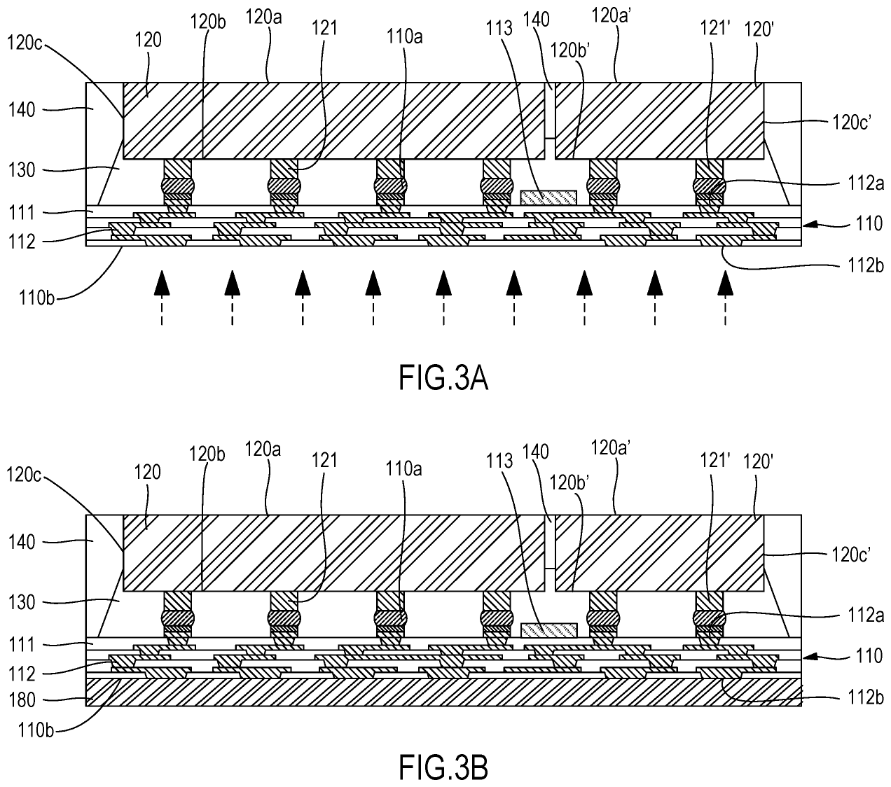

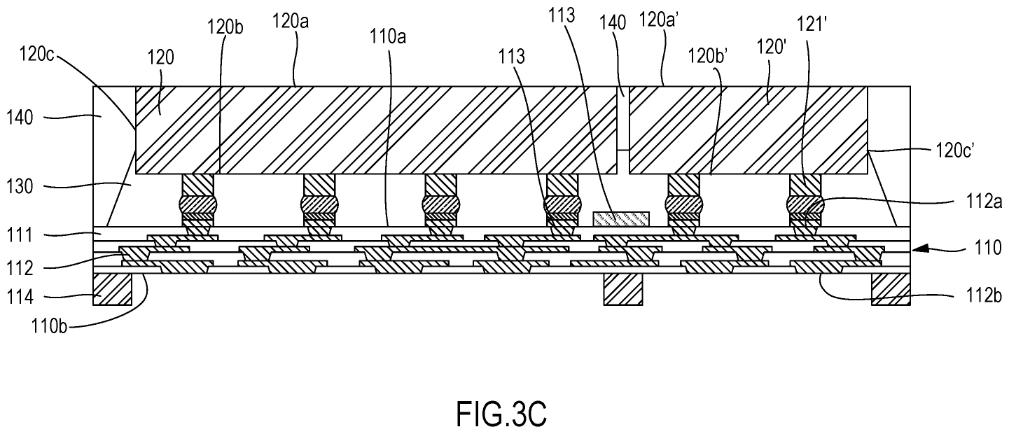

FIGS. 3A to 3C show cross-sectional views of an example method for manufacturing an electronic device, such as electronic device 100. Electronic device 100 provided by the method of FIGS. 3A to 3C can be similar or same as previously described. The method of FIGS. 3A to 3C can use similar processes to those described with FIGS. 2A to 2G. In this regard, distinctions between the process of FIGS. 2A to 2G will be discussed hereinafter. FIG. 3A shows a cross-sectional view of electronic device 100 at an early stage of manufacture. In the example shown in FIG. 3A, carrier 160 can be removed. In some examples, carrier 160 is completely removed exposing substrate outer side 110b.

In some examples, carrier 160 can be separated from substrate 110. For example, a wafer support system can first be attached to encapsulant 140 or electronic components 120 and 120′, and then carrier 160 can then be removed from substrate 110. In some examples, when a temporary adhesive film is interposed between substrate 110 and carrier 160, the temporary adhesive film can be exposed to heat or light (e.g., laser beam) to lower the adhesion of the temporary adhesive film, thereby facilitating the removal of carrier 160 from substrate 110. In some examples, carrier 160 mechanical force can be used to separate carrier 160 and substrate 110. In some examples, carrier 160 can be removed by mechanical grinding or chemical etching. By removing or separating carrier 160, substrate outer side 110b of substrate 110 can be exposed. In some examples, some regions of dielectric structure 111 and some regions of conductive structure 112 can be exposed. In some examples, substrate outward terminals 112b of substrate 110 can be exposed.

FIG. 3B shows a cross-sectional view of electronic device 100 at a later stage of manufacture. In the example shown in FIG. 3B, a coating 180, such as an organic material coating 180 can be provided. In some examples, a polymer coating 180 can be provided.

In some examples, coating 180 can be provided over substrate outer side 110b of substrate 110. In some examples, a polymer, such as PI, BCB, PBO, resin, or ABF, can be coated, laminated, or deposited on the entire substrate outer side 110b of substrate 110. For example, coating 180 can be provided using spin coating, spray coating, dip coating, or rod coating and then cured. In some examples, coating 180 can be provided by CVD, PVD, ALD, LPCVD, or PECVD. In some examples, coating 180 can have a thickness of about 1 μm to about 200 μm.

FIG. 3C shows a cross-sectional view of electronic device 100 at a later stage of manufacture. In the example shown in FIG. 3C, external stiffener structure 114 can be provided by patterning coating 180.

In some examples, to provide external stiffener structure 114 a selective removal process such as photoresist process can be used. For example, photoresist can be applied on polymer coating layer 180. A photoresist pattern can remain on coating 180 by placing a photomask on the photoresist, performing an exposure process, and then performing a development process. An exposed region of coating 180 can be removed by etching and using the photoresist pattern as a mask. In some examples, a partial region of coating 180 can be etched by dry etching or wet etching. In some examples, in the case of dry etching, the partial region of coating 180 can be removed by providing an etching gas (e.g., a mixed gas of a fluorocarbon compound and oxygen, etc.) in a plasma state to the partial region of coating 180. In some examples, after the etching, dielectric structure 111 and conductive structure 112 of substrate 110 can be exposed. In some examples, substrate outward terminals 112b of substrate 110 can be exposed. In some examples, after the etching, the photoresist pattern can be stripped using processes similar to those described previously. In such a manner, external stiffener structure 114 can be provided coupled including attached to substrate outer side 110b of substrate 110. In some examples, external stiffener structure 114 comprising a polymer can be provided in a substantially rectangular line shape along lateral sides 110c, 110d, 110e, and 110f of substrate 110, or can be provided in a straight-line traversing along the length direction or width direction of substrate 110. In some examples, external stiffener structure 114 comprising a polymer can have a thickness of about 1 μm to about 200 μm. External stiffener structure 114 comprising a polymer can suppress or reduce bending and warpage of electronic device 100 or can also function as a stopper.

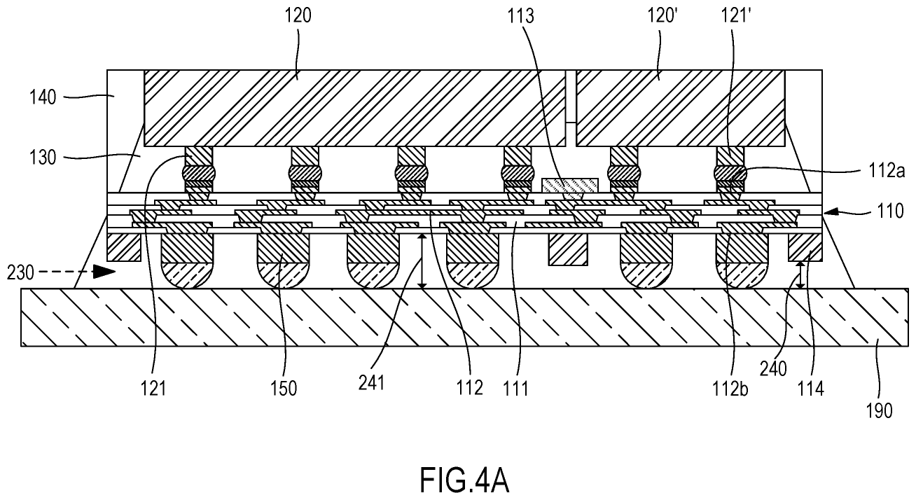

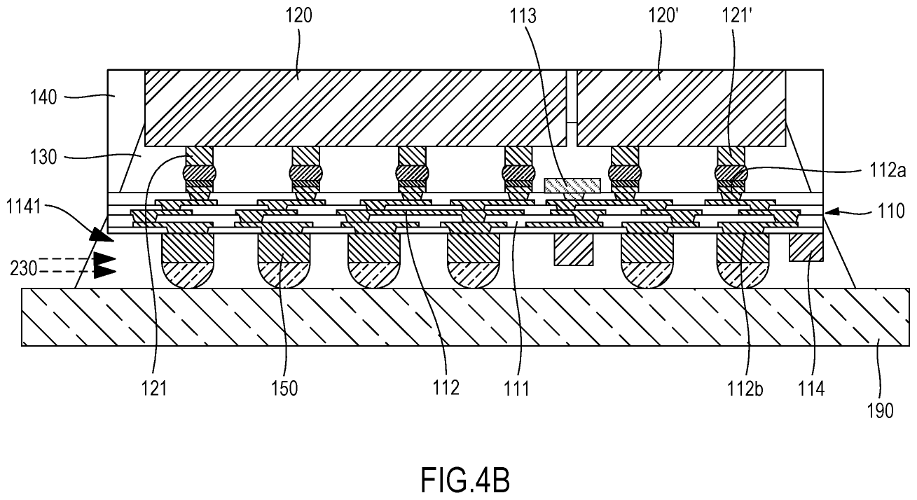

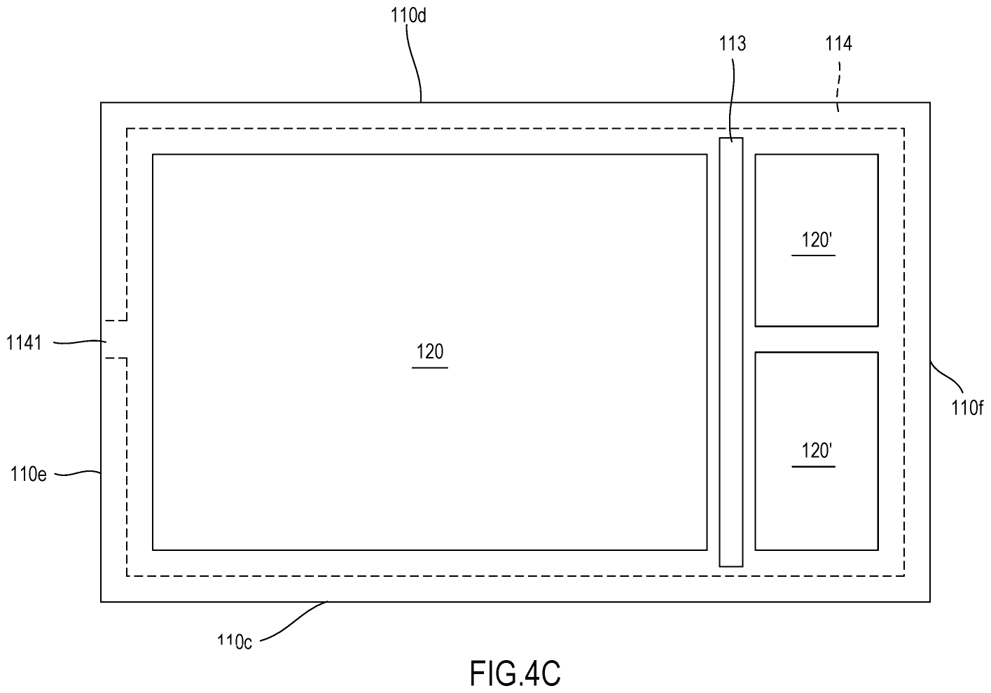

FIG. 4A shows a cross-sectional view of an example electronic device 100. In the example shown in FIG. 4A, a second underfill 230 can be provided between electronic device 100 and external device 190 (e.g., a printed circuit board). For example, a capillary underfill can be provided to a gap 240 between electronic device 100 and external device 190. Since gap 240 between external stiffener structure 114 and external device 190 is smaller than a gap 241 between substrate 110 and external device 190, thereby making it difficult to fill the capillary underfill. These can result in defects, such as voids.

FIG. 4B shows a cross-sectional view of an example electronic device 100 and FIG. 4C shows a top view of an example electronic device 100. In the examples shown in FIGS. 4B and 4C, at least a region of external stiffener structure 114 can be removed. In some examples, through-hole 1141 can be provided in a region of external stiffener structure 114. For example, through-hole 1141 can be provided extending through a side portion of external stiffener structure 114. In some examples, the substrate outer side 110b substrate 110 (for example, dielectric structure 111 or conductive structure 112) can be exposed through through-hole 1141. In some examples, underfill 230 can be smoothly filled into gap 241 between substrate 110 and external device 190 through through-hole 1141. In this way, voids can be suppressed or reduced between substrate 110 and external device 190. In some examples, through-hole 1141 can have a width of about 30 μm to about 1000 μm, and, in this range, the underfill can be easily injected, and the function of external stiffener structure 114 may not be adversely affected. Underfill 230 can be materials similar to underfill 130 and can be provided using similar processes described with underfill 130.

In summary, structures and associated methods have been described that relate to electronic devices with 3D wafer level packaging. More particularly, structures and methods have been described that improve the reliability of wafer level substrates, such as redistribution layer (RDL) substrates used, for example, in fine-pitch fan-out configurations. In some examples, the substrate stiffeners can be used to reduce warpage, module bending, and stress-related defects, such as cracks. In some examples, an external substrate stiffener can provide a stopper function, which reduces unwanted bending when the electronic devices are attached to a next level of assembly. The structures and methods were found in practice to improve mechanical strength by 1.5 to 2 times compared to previous electronic devices.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a substrate inner side;
a substrate outer side opposite to the substrate inner side;
substrate lateral sides connecting the substrate inner side to the substrate outer side;
a dielectric structure;
a conductive structure comprising:
substrate inward terminals adjacent to the substrate inner side; and
substrate outward terminals adjacent to the substrate outer side;
and
a substrate internal stiffener at the substrate inner side;
a first electronic component coupled to the substrate inward terminals and comprising:
a first lower side proximate to the substrate inner side;
a first upper side opposite to the first lower side; and
a first lateral side connecting the first lower side to the first upper side;
an underfill between the first lower side of the first electronic component and the substrate inner side and covering the substrate internal stiffener; and
an encapsulant covering a portion of the substrate inner side, a portion of the underfill; and a portion of the first electronic component.

2. The electronic device of claim 1, further comprising:
a second electronic component coupled to the substrate inward terminals and comprising:
a second lower side;
a second upper side opposite to the second lower side; and
a second lateral side connecting the second lower side to the second upper side;
wherein:
the second electronic component is laterally spaced apart from the first electronic component;
the substrate internal stiffener is between the first electronic component and the second electronic component; and
the underfill is between the second lower side of the second electronic component and the substrate inner side.

3. The electronic device of claim 2, wherein:
the encapsulant comprises an encapsulant top side;
the first upper side of the first electronic component and the second upper side of the second electronic component are exposed from the encapsulant top side;
the underfill is laterally between the first electronic component and the second electronic component;
a portion of the encapsulant top side is between the first electronic component and the second electronic component; and
the portion of the encapsulant top side contacts the underfill.

4. The electronic device of claim 1, wherein:
the substrate internal stiffener has a first thickness;
the substrate inward terminals comprise a second thickness; and
the first thickness is different than the second thickness.

5. The electronic device of claim 1, wherein:
the substrate comprises a redistribution layer (RDL) substrate;
the substrate comprises a pair of opposing lateral sides;
the substrate internal stiffener extends generally perpendicular between the pair of opposing lateral sides; and
ends of the substrate internal stiffener are inset from the pair of opposing lateral sides of the substrate.

6. The electronic device of claim 1, further comprising:
an external stiffener structure coupled to the substrate outer side.

7. The electronic device of claim 6, wherein:
the substrate outer side comprises a peripheral region; and
the external stiffener structure extends along the peripheral region.

8. The electronic device of claim 6, wherein:
the external stiffener structure comprises a side portion and a through-hole extending through the side portion.

9. The electronic device of claim 6, further comprising:
external interconnects coupled to the conductive structure proximate to the substrate outer side and comprising a first external interconnect and a second external interconnect laterally separated from the first external interconnect;
wherein:
the external stiffener structure comprises a substrate external stiffener interposed between the first external interconnect and the second external interconnect; and
the substrate internal stiffener and the substrate external stiffener overlap in a cross-sectional view.

10. The electronic device of claim 1, wherein:
the substrate internal stiffener comprises a conductor and is coupled to the conductive structure of the substrate.

11. An electronic device, comprising:
a substrate comprising:
a substrate inner side;
a substrate outer side opposite to the substrate inner side;
substrate lateral sides connecting the substrate inner side to the substrate outer side;
a dielectric structure;
a conductive structure comprising substrate inward terminals adjacent to the substrate inner side and substrate outward terminals adjacent to the substrate outer side; and
a substrate internal stiffener adjacent to the substrate inner side;
a first electronic component coupled to the substrate inward terminals and comprising:
a first lower side proximate to the substrate inner side;
a first upper side opposite to the first lower side; and
a first lateral side connecting the first lower side to the first upper side;
a second electronic component coupled to the substrate inward terminals, laterally spaced apart from the first electronic component, and comprising:
a second lower side;
a second upper side opposite to the second lower side; and
a second lateral side connecting the second lower side to the second upper side; and
an encapsulant covering a portion of the substrate inner side, a portion of the first electronic component, and a portion of the second electronic component.

12. The electronic device of claim 11, wherein:
the substrate internal stiffener is between the first electronic component and the second electronic component.

13. The electronic device of claim 11, further comprising:
component interconnects coupling the first lower side of the first electronic component and the second lower side of the second electronic component to the conductive structure; and
an underfill surrounding the component interconnects.

14. The electronic device of claim 11, further comprising:
an underfill between the first lower side of the first electronic component and the substrate inner side, between the second lower side of the second electronic component and the substrate inner side, and covering the substrate internal stiffener; and
a substrate external stiffener adjacent to the substrate outer side;
wherein:
the encapsulant covers a portion of the underfill; and
the substrate external stiffener and the substrate internal stiffener overlap in a cross-sectional view.

15. A method of manufacturing an electronic device comprising:
providing a substrate comprising:
a substrate inner side;
a substrate outer side opposite to the substrate inner side;
substrate lateral sides connecting the substrate inner side to the substrate outer side;
a dielectric structure;
a conductive structure comprising:
substrate inward terminals adjacent to the substrate inner side; and
substrate outward terminals adjacent to the substrate outer side;
and
a substrate internal stiffener coupled to the substrate inner side;
coupling a first electronic component to the substrate inward terminals, the first electronic component comprising:
a first lower side proximate to the substrate inner side;
a first upper side opposite to the first lower side; and
a first lateral side connecting the first lower side to the first upper side;
providing a first underfill between the first lower side of the first electronic component and the substrate inner side and covering the substrate internal stiffener;
providing an encapsulant covering at least a portion of the substrate inner side, at least portion of the first underfill; and at least a portion of the first electronic component;
providing an external stiffener structure coupled to the substrate outer side; and
providing external interconnects coupled to the substrate outward terminals.

16. The method of claim 15, further comprising:
coupling a second electronic component to the substrate inward terminals, the second electronic component comprising:
a second lower side proximate;
a second upper side opposite to the second lower side; and
second lateral side connecting the second lower side to the second upper side;
wherein:
the second electronic component is laterally spaced apart from the first electronic component;
the substrate internal stiffener is between the first electronic component and the second electronic component; and
providing the first underfill comprises providing the first underfill between the second lower side of the second electronic component and the substrate inner side.

17. The method of claim 15, further comprising:
providing an external device;
coupling the external interconnects to the external device; and
providing a second underfill between the substrate outer side and the external device;
wherein:
providing the external stiffener structure comprises providing a through-hole in a side portion of the external stiffener structure; and
providing the second underfill comprises providing the second underfill through the through-hole.

18. The method of claim 15, wherein:
providing the substrate comprises providing a redistribution layer (RDL) substrate.

19. The method of claim 15, wherein:
providing the substrate comprises:
providing a carrier comprising a carrier top side, a carrier bottom side opposite to the carrier top side, and a carrier thickness;
providing the substrate on the carrier top side;
reducing the carrier thickness; and
selectively removing a first portion of the carrier while leaving a second portion of the carrier coupled to the substrate outer side;
wherein the second portion defines the external stiffener structure.

20. The method of claim 15, wherein:
providing the substrate comprises:
providing a carrier comprising a carrier top side and a carrier bottom side opposite to the carrier top side;
providing the substrate on the carrier top side;
removing the carrier to expose the substrate outer side;
providing a coating over the substrate outer side; and
selectively removing portions of the coating to define the external stiffener structure.
